(19) United States
(12) Patent Application Publication
(10) Pub. No.: US 2015/0032246 A1
(43) Pub. Date: Jan. 29, 2015

(54) ENERGY-CONSUMPTION MONITORING SYSTEM FOR SUBSTRATE PROCESSING APPARATUS AND ENERGY-CONSUMPTION MONITORING METHOD FOR SUBSTRATE PROCESSING APPARATUS

(71) Applicant: TOKYO ELECTRON LIMITED, Minato-ku (JP)

(72) Inventors: Taku Mizutani, Fuchu-shi (JP); Ichiro Namioka, Fuchu-shi (JP); Kazushi Mori, Koshi-shi (JP)

(73) Assignee: TOKYO ELECTRON LIMITED, Minato-ku (JP)

(21) Appl. No.: 14/481,010

(22) Filed: Sep. 9, 2014

Related U.S. Application Data
(63) Continuation of application No. PCT/JP2013/001427, filed on Mar. 7, 2013.

(30) Foreign Application Priority Data
Mar. 9, 2012 (JP) 2012-053403

(51) Int. Cl. H01L 21/02

(52) U.S. Cl. CPC H01L 21/02002
USPC 700/121

(57) ABSTRACT

An energy-consumption monitoring system for a substrate processing apparatus includes a data collection device which collects process implementation data of a process to be executed according to each recipe in a substrate processing apparatus, a memory device which stores energy consumption data that indicate relationship between an individual energy-consuming event in the process and an amount of energy consumed per unit time by the individual energy-consuming event, and a computation device which detects an occurrence of the individual energy-consuming event and virtually calculate a cumulative energy consumption based on a duration of the individual energy-consuming event and the energy consumption data of the individual energy-consuming event stored in the memory device.

### CROSS-REFERENCE RELATED APPLICATIONS

The present application is a continuation of PCT/JP2013/001427, filed Mar. 7, 2013, which is based upon and claims the benefit of priority to Japanese Patent Application No. 2012-053403, filed Mar. 9, 2012. The entire contents of these applications are incorporated herein by reference.

### BACKGROUND OF THE INVENTION

1. Field of the Invention

The present invention relates to an energy-consumption monitoring system for a substrate processing apparatus and to a method for monitoring the energy consumption of a substrate processing apparatus.

2. Description of Background Art

To manufacture semiconductor devices, flat-panel display substrates, solar panels and the like, numerous substrate processing apparatuses are used. For example, various substrate processing apparatuses for treating semiconductor wafers such as a cleaning apparatus, coating-developing apparatus, etching apparatus, film-forming apparatus, thermal treatment apparatus or the like are used for manufacturing semiconductor devices (for example, see JP2012-19156A). The entire contents of this publication are incorporated herein by reference.

### SUMMARY OF THE INVENTION

According to one aspect of the present invention, an energy-consumption monitoring system for a substrate processing apparatus includes a data collection device which collects process implementation data of a process to be executed according to each recipe in a substrate processing apparatus, a memory device which stores energy consumption data that indicate relationship between an individual energy-consuming event in the process and an amount of energy consumed per unit time by the individual energy-consuming event, and a computation device which detects an occurrence of the individual energy-consuming event and virtually calculate a cumulative energy consumption based on a duration of the individual energy-consuming event and the energy consumption data of the individual energy-consuming event stored in the memory device.

According to another aspect of the present invention, an energy-consumption monitoring method for a substrate processing apparatus includes collecting process implementation data of a process to be executed according to each recipe in a substrate processing apparatus, storing in a memory device energy consumption data that indicate relationship between an individual energy-consuming event in the process and an amount of energy consumed per unit time by the individual energy-consuming event, and detecting an occurrence of the individual energy-consuming event and virtually calculating a cumulative energy consumption based on a duration of the individual energy-consuming event and the energy consumption data of the individual energy-consuming event stored in the memory device.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a diagram showing the structure of an embodiment of the present invention;

FIG. 2 is a view illustrating a method for computing energy consumption; and

FIG. 3 is a view showing an example of the screen for registering energy consumption data.

### DETAILED DESCRIPTION OF THE EMBODIMENTS

The embodiments will now be described with reference to the accompanying drawings, wherein like reference numerals designate corresponding or identical elements throughout the various drawings.

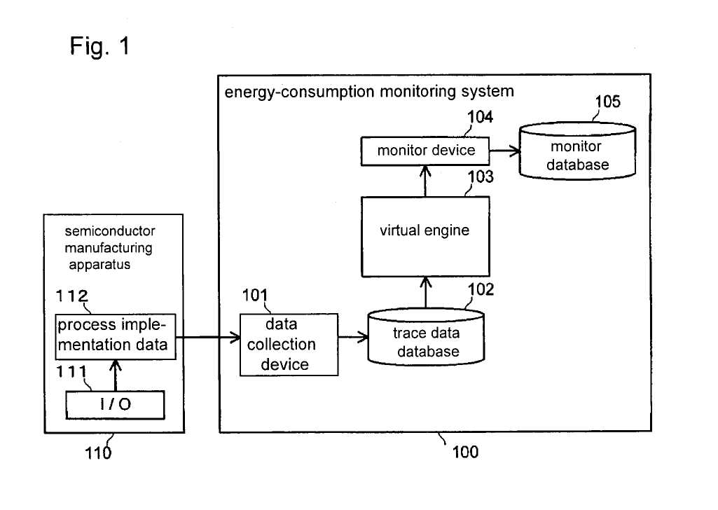

FIG. 1 is a diagram schematically illustrating the structure of an energy-consumption monitoring system for a substrate processing apparatus according to an embodiment of the present invention. In FIG. 1, reference numeral 100 indicates an energy-consumption monitoring system for a substrate processing apparatus, and 110 indicates a substrate processing apparatus, which is a semiconductor wafer cleaning apparatus in the present embodiment.

Substrate processing apparatus (semiconductor wafer cleaning apparatus) 110 has a structure of a cleaning apparatus such as follows:

a spin chuck which is set to be rotatable while suction-holding a semiconductor wafer; multiple nozzles to supply a chemical liquid for cleaning, pure water for rinsing, or the like onto a front surface of a semiconductor wafer held on the spin chuck; a cup which is positioned to surround the semiconductor wafer held on the spin chuck; and so on.

Substrate processing apparatus 110 is structured to conduct cleaning and drying of a semiconductor wafer by supplying a chemical liquid for cleaning, pure water for rinsing, or the like from multiple nozzles onto a semiconductor wafer held on the spin chuck, and by rotating the semiconductor wafer so as to spin off the chemical liquid, pure water for rinsing or the like.

In addition to being used as a cleaning apparatus, substrate processing apparatus 110 may be used as, for example, a coating-developing apparatus to coat photoresist on a semiconductor wafer (target substrate) and to develop the photoresist; an etching apparatus to conduct etching on a semiconductor wafer (target substrate); a film-forming apparatus to form film on a semiconductor wafer (target substrate); a thermal processing apparatus to conduct heat treatment on a semiconductor wafer (target substrate); and so on.

Energy-consumption monitoring system 100 for a substrate processing apparatus has data collection device 101, trace data database 102, virtual engine 103, monitor device 104 and monitor database 105.

From I/O port 111 of substrate processing apparatus 110, process implementation data 112 is output for a process to be executed in substrate processing apparatus 110 according to each recipe. Process implementation data 112 from substrate processing apparatus 110 is input into data collection device 101 of energy-consumption monitoring system 100 for a substrate processing apparatus, and is stored in trace data database 102. Virtual engine 103 is equipped with a memory device and a computation device: the memory device stores energy consumption data which show the relationship between an energy-consuming event in a process to be executed in substrate processing apparatus 110 and the amount of energy consumed by the event; and the computation device detects the occurrence of an energy-consuming event in the process implementation data that are input from substrate processing apparatus 110 to data collection device 101 and are stored in trace data database 102, and virtually calculates the cumulative energy consumption based on the duration of the event and the energy consumption data of the event stored in the memory device.

Namely, based on process implementation data 112 stored in trace data database 102, virtual engine 103 detects an event executed in the process and its duration at every predetermined time, which is at every second in the present embodiment. Then, virtual engine 103 calculates the cumulative energy consumption by the event based on the duration of the event and the amount of energy consumption per unit time preregistered in the memory device for each event (energy consumption data).

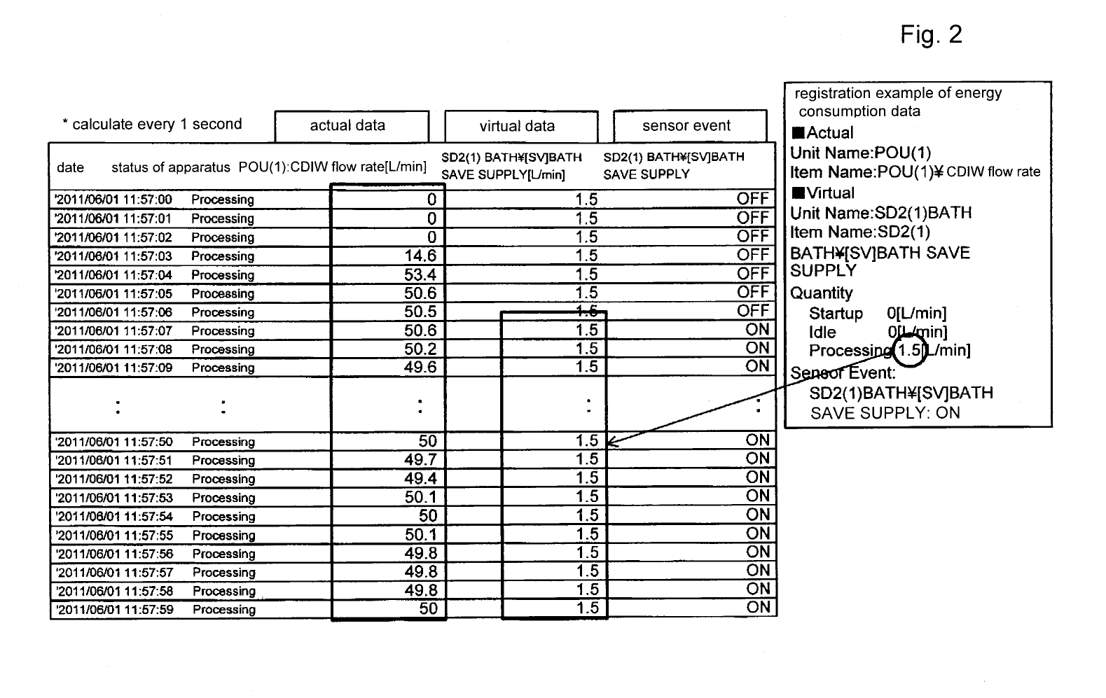

Monitor device 104 sums up the energy consumption calculated by virtual engine 103 and stores it in monitor database 105, while displaying the stored data. As shown in FIG. 2, to calculate energy consumption, virtual engine 103 detects the occurrence of an event to be executed in the process (sensor event shown in FIG. 2), and calculates cumulative energy consumption as virtual data while the sensor event is on.

In the leftmost column of FIG. 2, date and time for each event are indicated along with its status in the apparatus shown to the right of time. In FIG. 2, “processing” appears as a device status. In addition to “processing,” which indicates that the device is running during the process, there are other device statuses, such as “startup,” which indicates a device is activating an event, “idle,” which indicates the device is idling, and the like as shown on the rightmost in FIG. 2.

As shown in an example of energy consumption registration, the amount of energy to be consumed per unit time while a sensor event is on is preregistered as energy consumption data. In the registration example of energy consumption in FIG. 2, it is 0 (L/min) when the device status is “startup,” 0 (L/min) when the status is “idle,” and 1.5 (L/min) when it is “processing.” In the above example, since the unit of the virtual data is L/min for flow rates, the energy consumption is calculated by converting the data to the amount of energy consumption per second as described later.

Actual data are also shown in FIG. 2. However, since no event conditions are specified for actual data, actual cumulative value for the entire duration is calculated. In the example shown in FIG. 2, the unit for actual data is also set as L/min. Thus, the value of energy consumption is obtained by converting the data to energy consumption per second, the same as for the virtual data described above.

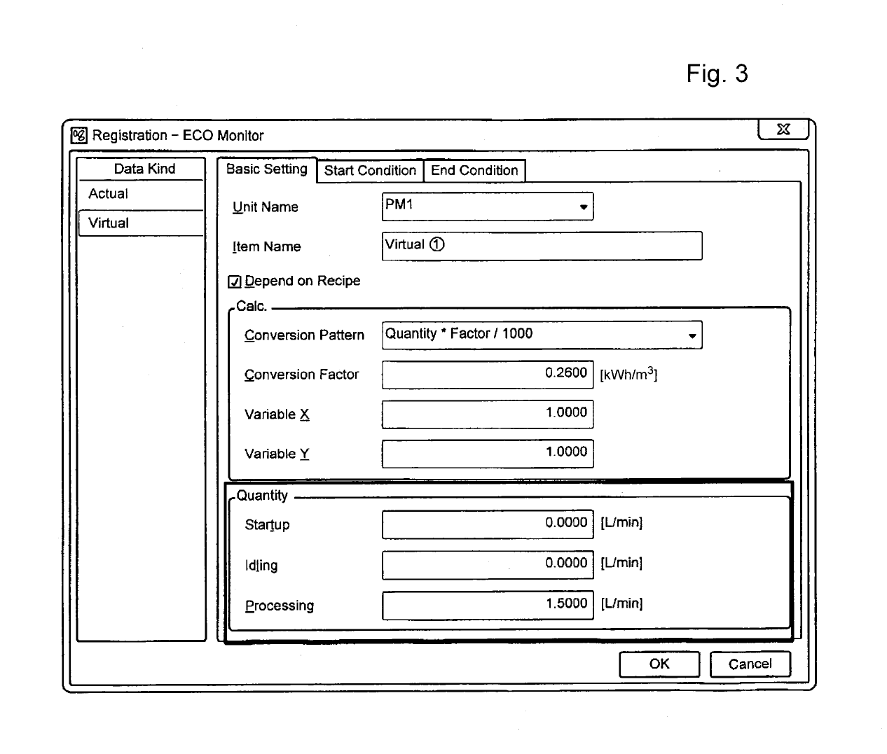

FIG. 3 shows an example of the screen for registering energy consumption data in virtual engine 103. In the registration screen shown in FIG. 3, the target is specified by a unit name, item name or the like. Then, a formula or a numeric value or the like is registered to be used for converting the aforementioned flow rates to energy consumption by a conversion pattern, conversion factor or the like. The registered contents are stored in the memory device in virtual engine 103, and are called to be used for calculation of energy consumption.

In the example shown in FIG. 3, the conversion pattern is Quantity×Factor/1000, the conversion factor is 0.2600 (kWh/m³), variable X is 1.0000, and variable Y is 1.0000.

Numeric values are each registered to be used when the device status is “startup,” “idling,” or “processing.” In the example shown in FIG. 3, the values are 0.0000 (L/min) when the status is “startup” or “idling,” and 1.5000 (L/min) when the status is “processing.”

In energy-consumption monitoring system 100 for a substrate processing apparatus structured as above, without providing substrate processing apparatus 110 with various sensors for measuring energy consumption or a data collection device for collecting data measured by such sensors, the amount of energy consumed in substrate processing apparatus 110 is virtually calculated and displayed by inputting process implementation data 112 for a process to be executed in substrate processing apparatus 110 according to each recipe.

Accordingly, an increase in manufacturing cost is suppressed while energy consumption is monitored in substrate processing apparatus 110.

In the aforementioned energy-consumption monitoring system 100 for a substrate processing apparatus, the energy consumption is virtually calculated and displayed without using various sensors for measuring energy consumption. As a result, the virtually calculated amount of energy consumption may deviate from the actual value of energy consumption. Thus, it is preferred to perform calibration at any selected time so that the value of virtually calculated energy consumption accurately matches the value of actually measured energy consumption.

To perform the aforementioned calibration, for example, a sensor is installed for measuring the energy consumption in each device of substrate processing apparatus 110 at the time of maintenance or the like on substrate processing apparatus 110. Then, parameters and the like are modified to be used when energy consumption is calculated in virtual engine 103 so that the value of the energy consumption virtually calculated by energy-consumption monitoring system 100 of the substrate processing apparatus matches the value of the energy consumption measured by such sensors. Accordingly, the energy consumption virtually calculated by energy-consumption monitoring system 100 of the substrate processing apparatus accurately matches the actual energy consumption.

The present invention is not limited to the embodiment described above, and various modifications are possible. For example, in the above embodiment, energy-consumption monitoring system 100 for a substrate processing apparatus is provided separately from substrate processing apparatus 110. However, it is an option for energy-consumption monitoring system 100 for a substrate processing apparatus to be integrated into substrate processing apparatus 110. Also, in such a case, functions of trace data database 102, virtual engine 103, monitor device 104, and monitor database 105 may be integrated into the control computer to control operations of substrate processing apparatus 110.

The model for calculating the energy consumption in virtual engine 103 is not limited to the above, and any other model may be used.

Energy-consumption monitoring system 100 for a substrate processing apparatus according to an embodiment of the present invention may also be used in various manufacturing sectors such as manufacturing semiconductor devices, flat-panel display substrates, solar panels and the like. Thus, its industrial applicability is high.

A substrate processing apparatus uses much energy in its substrate processing steps. Thus, it is thought to be necessary for the substrate processing apparatus to save energy and to estimate the level of energy consumption from the viewpoints of lowering environmental load and reducing the cost of running the apparatus.

To display energy consumption in a substrate processing apparatus, it is thought to be necessary to install a sensor for measuring the amount of power or the like that is actually being consumed, to install a data collection device for collecting the data measured by the sensor, and to display energy consumption based on the value measured by the sensor.

To display energy consumption in a substrate processing apparatus as described above, it is necessary to install numerous sensors and a data collection device for collecting the measured data from the sensors, and thus the cost increases in manufacturing the substrate processing apparatus.

Using an energy-consumption monitoring system for a substrate processing apparatus according to an embodiment of the present invention and an energy-consumption monitoring method for a substrate processing apparatus according to another embodiment of the present invention, an increase in the cost of manufacturing the apparatus is suppressed and its energy consumption is monitored.

According to an embodiment of the present invention, an energy-consumption monitoring system for a substrate processing apparatus monitors energy consumption in a substrate processing apparatus that conducts predetermined treatment on target substrates. Such a monitoring system is characterized by having a memory device and a computation device: the memory device stores energy-consumption data that show the relationship between an energy-consuming event in a process to be executed in the substrate processing apparatus and the amount of energy consumed by the event; and the computation device collects process implementation data from the substrate processing apparatus, detects the occurrence of an energy-consuming event, and calculates the cumulative energy consumption based on the duration of the event and the energy-consumption data of the event stored in the memory device.

According to another embodiment of the present invention, the energy-consumption monitoring method for a substrate processing apparatus is for monitoring energy consumption in a substrate processing apparatus that performs predetermined treatment on a target substrate. Such a method is characterized by including the following steps: in a memory device, storing energy consumption data that show the relationship between an energy-consuming individual event in a process and the amount of energy consumed by the event; and collecting process implementation data from the substrate processing apparatus, detecting the occurrence of an energy-consuming event, and virtually calculating the cumulative energy consumption based on the duration of the event and the energy consumption data of the event stored in the memory device.

Using an energy-consumption monitoring system for a substrate processing apparatus according to an embodiment of the present invention and an energy-consumption monitoring method for a substrate processing apparatus according to another embodiment of the present invention, an increase in manufacturing cost is suppressed and energy consumption is monitored.

Obviously, numerous modifications and variations of the present invention are possible in light of the above teachings. It is therefore to be understood that within the scope of the appended claims, the invention may be practiced otherwise than as specifically described herein.

What is claimed is:

1. An energy-consumption monitoring system for a substrate processing apparatus, comprising:
a data collection device configured to collect process implementation data of a process to be executed according to each recipe in a substrate processing apparatus;
a memory device configured to store energy consumption data that indicate relationship between an individual energy-consuming event in the process and an amount of energy consumed per unit time by the individual energy-consuming event; and
a computation device configured to detect an occurrence of the individual energy-consuming event and virtually calculate a cumulative energy consumption based on a duration of the individual energy-consuming event and the energy consumption data of the individual energy-consuming event stored in the memory device.

2. The energy-consumption monitoring system according to claim 1, wherein the computation device is configured to calculate the cumulative energy consumption without data measured by an individual sensor for measuring an energy consumption.

3. The energy-consumption monitoring system according to claim 1, further comprising:
a registration device configured to register the energy consumption data that indicate the relationship between the individual energy-consuming event in the process and the amount of energy consumed per unit time by the individual energy-consuming event.

4. The energy-consumption monitoring system according to claim 2, further comprising:
a registration device configured to register the energy consumption data that indicate the relationship between the individual energy-consuming event in the process and the amount of energy consumed per unit time by the individual energy-consuming event.

5. The energy-consumption monitoring system according to claim 1, further comprising:
a calibration device configured to calibrate the energy consumption data stored in the memory device based on a measured energy consumption consumed in the substrate processing apparatus.

6. The energy-consumption monitoring system according to claim 2, further comprising:
a calibration device configured to calibrate the energy consumption data stored in the memory device based on a measured energy consumption consumed in the substrate processing apparatus.

7. The energy-consumption monitoring system according to claim 3, further comprising:
a calibration device configured to calibrate the energy consumption data stored in the memory device based on a measured energy consumption consumed in the substrate processing apparatus.

8. The energy-consumption monitoring system according to claim 4, further comprising:
a calibration device configured to calibrate the energy consumption data stored in the memory device based on a measured energy consumption consumed in the substrate processing apparatus.

9. The energy-consumption monitoring system according to claim 1, wherein the substrate processing apparatus is one of a cleaning apparatus configured clean a substrate, a coating-developing apparatus configured to coat photoresist on a substrate and develop the photoresist, an etching apparatus configured to conduct etching on a substrate, a film-forming apparatus configured to form film on a substrate, and a thermal processing apparatus configured to conduct heat treatment on a substrate.

10. The energy-consumption monitoring system according to claim 2, wherein the substrate processing apparatus is one of a cleaning apparatus configured clean a substrate, a coating-developing apparatus configured to coat photoresist on a substrate and develop the photoresist, an etching apparatus configured to conduct etching on a substrate, a film-forming apparatus configured to form film on a substrate, and a thermal processing apparatus configured to conduct heat treatment on a substrate.

11. The energy-consumption monitoring system according to claim 3, wherein the substrate processing apparatus is one of a cleaning apparatus configured clean a substrate, a coating-developing apparatus configured to coat photoresist on a substrate and develop the photoresist, an etching apparatus configured to conduct etching on a substrate, a film-forming apparatus configured to form film on a substrate, and a thermal processing apparatus configured to conduct heat treatment on a substrate.

12. The energy-consumption monitoring system according to claim 4, wherein the substrate processing apparatus is one of a cleaning apparatus configured clean a substrate, a coating-developing apparatus configured to coat photoresist on a substrate and develop the photoresist, an etching apparatus configured to conduct etching on a substrate, a film-forming apparatus configured to form film on a substrate, and a thermal processing apparatus configured to conduct heat treatment on a substrate.

13. The energy-consumption monitoring system according to claim 5, wherein the substrate processing apparatus is one of a cleaning apparatus configured clean a substrate, a coating-developing apparatus configured to coat photoresist on a substrate and develop the photoresist, an etching apparatus configured to conduct etching on a substrate, a film-forming apparatus configured to form film on a substrate, and a thermal processing apparatus configured to conduct heat treatment on a substrate.

14. The energy-consumption monitoring system according to claim 6, wherein the substrate processing apparatus is one of a cleaning apparatus configured clean a substrate, a coating-developing apparatus configured to coat photoresist on a substrate and develop the photoresist, an etching apparatus configured to conduct etching on a substrate, a film-forming apparatus configured to form film on a substrate, and a thermal processing apparatus configured to conduct heat treatment on a substrate.

15. The energy-consumption monitoring system according to claim 7, wherein the substrate processing apparatus is one of a cleaning apparatus configured clean a substrate, a coating-developing apparatus configured to coat photoresist on a substrate and develop the photoresist, an etching apparatus configured to conduct etching on a substrate, a film-forming apparatus configured to form film on a substrate, and a thermal processing apparatus configured to conduct heat treatment on a substrate.

16. The energy-consumption monitoring system according to claim 8, wherein the substrate processing apparatus is one of a cleaning apparatus configured clean a substrate, a coating-developing apparatus configured to coat photoresist on a substrate and develop the photoresist, an etching apparatus configured to conduct etching on a substrate, a film-forming apparatus configured to form film on a substrate, and a thermal processing apparatus configured to conduct heat treatment on a substrate.

17. A method for monitoring an energy-consumption of a substrate processing apparatus, comprising:
collecting process implementation data of a process to be executed according to each recipe in a substrate processing apparatus;
storing in a memory device energy consumption data that indicate relationship between an individual energy-consuming event in the process and an amount of energy consumed per unit time by the individual energy-consuming event; and
detecting an occurrence of the individual energy-consuming event and virtually calculating a cumulative energy consumption based on a duration of the individual energy-consuming event and the energy consumption data of the individual energy-consuming event stored in the memory device.

18. The method for monitoring an energy-consumption of a substrate processing apparatus according to claim 17, further comprising:
registering the energy consumption data that indicate the relationship between the individual energy-consuming event in the process and the amount of energy consumed per unit time by the individual energy-consuming event.

19. The method for monitoring an energy-consumption of a substrate processing apparatus according to claim 17, further comprising:
calibrating the energy consumption data stored in the memory device based on a measured energy consumption consumed in the substrate processing apparatus.

20. The method for monitoring an energy-consumption of a substrate processing apparatus according to claim 18, further comprising:
calibrating the energy consumption data stored in the memory device based on a measured energy consumption consumed in the substrate processing apparatus.
